(19) United States
(12) Patent Application Publication
(10) Pub. No.: US 2009/0290274 A1
(43) Pub. Date: Nov. 26, 2009

(54) REMOVABLE MEMORY CARD

(76) Inventors: Hiroshi SUENAGA, Osaka (JP); Yoshiyuki Saito, Osaka (JP); Osamu Shibata, Hyogo (JP); Yukihiro Fukumoto, Osaka (JP)

Correspondence Address: MCDERMOTT WILL & EMERY LLP, 600 13TH STREET, NW, WASHINGTON, DC, 20005-3096, US

(21) Appl. No.: 12/468,475

(22) Filed: May 19, 2009

(30) Foreign Application Priority Data
May 22, 2008 (JP) 2008-133760

(51) Int. Cl. H02H 9/04; H05K 1/02

(52) U.S. Cl. 361/56; 361/737

(57) ABSTRACT

According to the present invention, the setting height position of a first terminal is set to be lower than the setting height position of a second terminal on the terminal formation surface of a printed substrate, so that the protection of an internal circuit and the transmission of a high-speed signal can be both achieved.

### BACKGROUND OF THE INVENTION

1. Field of the Invention

The present invention relates to a removable memory card, more particularly to a card structure designed to avoid electrostatic breakdown caused by contact with a human body, etc.

2. Description of the Related Art

Most of removable memory cards comprise exposed terminals, and a user's fingertips possibly contact these terminals when he/she handles these cards. In the case where static electricity has already been accumulated in the user's body and contact is made with a removable memory card, an LSI provided in the removable memory card connected to the terminals may breakdown due to the static electricity.

In order to deal with the problem, in a removable memory card illustrated in FIG. 17 and FIG. 18 (a sectional surface of the card illustrated in FIG. 17 cut along A-B line), for example, a diode for eliminating static electricity is conventionally connected to an I/O circuit in an LSI 60 directly connected to terminals 31b of the removable memory card. In this structure, when static electricity intrudes into the removable memory card, the static electricity is bypassed such that it is discharged through the diode to a stable potential such as a ground or power-supply potential. As a result, the protection of the LSI 60 is carried out.

There is another technology concerning the problem, which is recited in the disclosed Japanese patent documents (60-153538 of the Japanese Patent Applications Laid-Open). A removable memory card wherein the technology is adopted is illustrated FIGS. 19 and 20. FIG. 19 is a perspective view of the removable memory card, while FIG. 20 is a sectional view of FIG. 10 cut long II-II line. In FIG. 19, terminals 31 of the removable memory card are coated with an elastomer layer 5 provided with notches 51. When the removable memory card is not connected to a reading device, the notches 51 are kept blocked due to the elasticity of the elastomer layer 5. When the removable memory card is connected to the reading device, a contact point 6 of the reading device advances into the notches 51 of the elastomer layer 5 to come into contact with and make connections to the terminals 31, as illustrated in FIG. 20. Accordingly, any contact between the fingertips, or the like, and the terminals can be prevented when the removable memory card is removed from the reading device.

A diode for eliminating static electricity needs to have such a load capacity as a few pF at least or approximately 10 pF at most. When the diode having such a large load capacity is provided, however, impedance mismatch occurs in a transmission wire. A transmission rate in the conventional removable memory card described earlier is as relatively low as approximately a few tens of Mbps/ch. Therefore, the provision of the diode for eliminating static electricity did not present a serious problem in dealing with impedance mismatch in a transmission wire due to its load capacity. However, removable memory cards now available have such a large memory capacity as a few gigabytes, and the memory capacity is expected to be further increased in the future. Along with the increasing memory capacity, the transmission rate of a removable memory card has become higher. Under the current circumstances, the load capacity of a diode for eliminating static electricity is becoming an inhibition in the pursuit of a higher transmission rate.

Furthermore, when the conventional technology is applied, it is indispensable to secure a large area for providing the elastomer layer 5. However, the increase of the memory capacity of a removable memory card necessitates the demand that a large mounting area to be secured for a flash memory provided in the removable memory card. Securing a flash memory mounting area has priority over the installation of the elastomer layer 5. As a result, an adequately large area cannot be allowed for the elastomer layer 5 to be attached, and there is a high possibility that the elastomer layer 5 is peeled off.

### SUMMARY OF THE INVENTION

Therefore, a main object of the present invention is to provide a removable memory card having a structure wherein the protection of an internal circuit and the transmission of a high-speed signal can be both realized.

In order to accomplish the main object, a removable memory card according to the present invention has such a structure that terminals for transmitting high-speed signals (these terminals correspond to a first terminal) are provided at positions lower than positions of terminals for transmitting low-speed signals and power-supply/ground terminals (these terminals correspond to a second terminal).

According to the constitution, when an object charged with static electricity, such as a human body, contacts the removable memory card, the electrostatically-charged object contacts the second terminal (terminals for transmitting low-speed signals and power-supply/ground terminals) before contacting the first terminals (terminals for transmitting high-speed signals). Therefore, the static electricity accumulated in the object can be flowed to the side of the second terminal. As a result, it becomes unnecessary to provide a diode for eliminating static electricity having a large load capacity in an I/O circuit portion in an LSI which are connected to the first terminals (terminals for transmitting high-speed signals) and a bypass wire.

According to the removable memory card provided by the present invention, impedance mismatch occurring in the transmission path connected to the terminals for transmitting high-speed signals (the first terminal) can be alleviated, and the electrostatic protection performance can be retained at the same time. As a result, a transmission rate of the removable memory card is improved.

The removable memory card according to the present invention, wherein the impedance mismatch occurring in the transmission path connected to the terminals for transmitting high-speed signals can be alleviated, and the electrostatic protection performance can be retained at the same time, is useful to improving its transmission rate.

### BRIEF DESCRIPTION OF THE DRAWINGS

These and other objects of the invention will become clear by the following description of preferred embodiments of the invention and be specified in the claims attached hereto. A number of benefits not recited in this specification will come to the attention of the skilled in the art upon the implementation of the present invention.

FIG. 1 is an illustration of an example of a removable memory card according to a preferred embodiment 1 of the present invention.

FIG. 2 is an illustration of an example of a sectional surface of the removable memory card illustrated in FIG. 1.

FIG. 3 is a configuration diagram wherein electrostatic breakdown is controlled.

FIG. 4 is an illustration of an example of the removable memory card according to the preferred embodiment 1.

FIG. 5 is an illustration of an example of a sectional surface of the removable memory card illustrated in FIG. 4.

FIG. 6 is an illustration of an example of the removable memory card according to the preferred embodiment 1.

FIG. 7 is an illustration of an example of a sectional surface of the removable memory card illustrated in FIG. 6.

FIG. 8 is an illustration of an example of a removable memory card according to a preferred embodiment 2 of the present invention.

FIG. 9 is an illustration of an example of a sectional surface of the removable memory card illustrated in FIG. 8.

FIG. 10 is an illustration of an example of the removable memory card according to the preferred embodiment 2.

FIG. 11 is an illustration of an example of a sectional surface of the removable memory card illustrated in FIG. 10.

FIG. 12 is an illustration of an example of the removable memory card according to the preferred embodiment 2.

FIG. 13 is an illustration of an example of a sectional surface of the removable memory card illustrated in FIG. 12.

FIG. 14A is a perspective view of a first modified embodiment of the present invention.

FIG. 14B is a perspective view of a second modified embodiment of the present invention.

FIG. 14C is a perspective view of a third modified embodiment of the present invention.

FIG. 15 is a sectional view used for the description of effects obtained by the first-third modified embodiments.

FIG. 16 is a sectional view of a fourth modified embodiment of the present invention.

FIG. 17 is an illustration of a conventional technology associated with the control of the electrostatic breakdown of a removable memory card.

FIG. 18 is a sectional view of the removable memory card illustrated in FIG. 17.

FIG. 19 is an illustration of another conventional technology associated with the control of the electrostatic breakdown of a removable memory card.

FIG. 20 is a sectional view of the removable memory card illustrated in FIG. 19.

### DETAILED DESCRIPTION OF THE INVENTION

Hereinafter, preferred embodiments of the present invention are described referring to the drawings.

### Preferred Embodiment 1

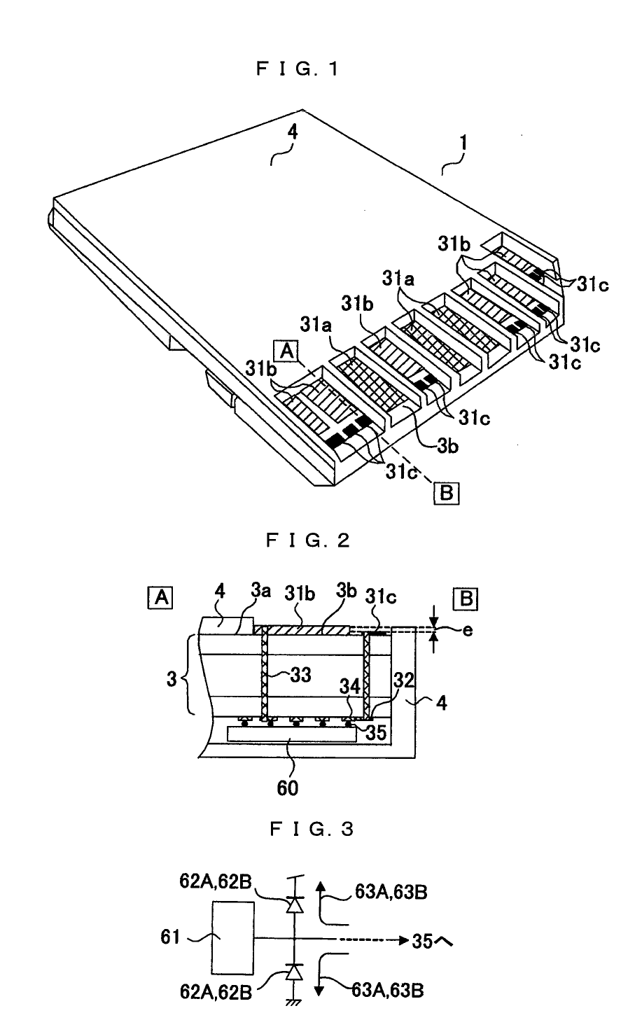

FIG. 1 is a perspective view of an example of a removable memory card according to a preferred embodiment 1 of the present invention. FIG. 2 is a sectional view of FIG. 1 cut along A-B line. The removable memory card according to the present preferred embodiment comprises a printed substrate 3. Terminals 31a, 31b and 31c used for connection to an outside host device are provided on a terminal formation surface 3a of the printed substrate 3. The terminals 31a, 31b and 31c are placed in a terminal setting section 3b provided at an end portion of the terminal formation surface 3a. On the printed substrate 3, an LSI 60 is mounted by means of solder bumps 35 or the like. The LSI 60 controls the read and write of data with respect to a flash memory (not shown) provided in the removable memory card 1 in response to requests such as data READ/WRITE from the outside host device (not shown). The LSI 60 is connected to the terminals 31a, 31b and 31c by means of a via 33 in the printed substrate 3 and wiring lines 32. The printed substrate 3 thus constituted is covered with a sheet 4 made of hard PVC (polyvinyl chloride) or the like.

The terminals 31a, 31b and 31c are as follows: a power-supply/ground terminal 31a, a terminal 31b for low-speed signal and a terminal 31c for high-speed signal. In the present preferred embodiment, the terminal 31c for high-speed signal constitutes a first terminal, while the power-supply/ground terminal 31a and the terminal 31b for low-speed signal constitutes a second terminal. The removable memory card 1 according to the present preferred embodiment is further provided with first and second bypass wires 63A and 63B as illustrated in FIG. 3. The second bypass wire 63B drops the static electricity having intruded into the terminal 31b for low-speed signal to a stable potential (a power-supply or ground potential) through a second diode 62B so that the static electricity is not inputted to an I/O circuit 61 in the LSI 60. The first bypass wire 63A drops the static electricity having intruded into the terminals 31c for high-speed signal to a stable potential (power supply or ground potential) through a first diode 62A so that the static electricity is not inputted to the I/O circuit 61 in the LSI 60. As the second diode 62B to be provided in the second bypass wire 63B is used a diode having a high pressure resistance and a large load capacity. On the other hand, as the first diode 62A to be provided in the first bypass wire 63A is used a diode having a small load capacity.

A transmission rate of a signal inputted from outside (host device or the like) to the terminals 31b for low-speed signal is approximately a few tens of Mbps/ch which is relatively low, while a transmission rate of a signal inputted from outside (host device or the like) to the terminals 31c for high-speed signal is very high, approximately a few giga bps/ch.

The present preferred embodiment is characterized in thicknesses of the terminals 31a, 31b and 31c. More specifically, the thickness of each of the power-supply/ground terminal 31a and the terminal 31b for low-speed signal is set to be larger than the thickness of the terminal 31c for high-speed signal. To realize the different thickness, for example, an arrangement is made to a metal plating process. More specifically, when surfaces of the terminals 31a, 31b and 31c are metal-plated, the surface of each of the terminal 31b for low-speed signal and the power supply and ground terminal 31a (second terminal) is metal-plated in a thickness larger than that of the surface of the terminal 31c for high-speed signal (first terminal) so that a difference in thickness is generated between the first and second terminals. In other words, a difference in the setting height position and a difference in the height position of the terminal surface (level difference e) are provided between the first and second terminals.

According to the constitution, when an electrostatically-charged user operates the removable memory card 1, and his/her fingertips, for example, contact the terminals 31a, 31b and 31c, the fingertips first contact the terminal 31b for low-speed signal which is thicker than the others. Therefore, the static electricity accumulated in the user's body flows through the terminal 31b for low-speed signal into the second diode 62B provided in the second bypass wire 63B, and further is discharged through the second diode 62B to the stable potential (power-supply potential or ground potential), or is discharged through the power-supply/ground terminal 31a to the stable potential. Accordingly, the I/O circuit 61 of the LSI 60 is protected from the static electricity.

In this case, because the transmission rate in the transmission of the signal through the terminal 31b for low-speed signal is low, impedance mismatch in the transmission path is not a major concern. On the other hand, because the transmission rate in the transmission of the signal through the terminal 31c for high-speed signal is high, the impedance mismatch in the transmission path can be a serious problem. In view of this, the following constitution has been provided in the present preferred embodiment as described earlier. In the second bypass wire 63B to which the terminals 31b for low-speed signal are connected, the second diode 62B having a sufficiently high pressure resistance and a large load capacity is provided. On the other hand, in the first bypass wire 63A to which the terminals 31c for high-speed signal are connected, the first diode 62A having a reduced load pressure resistance and a small load capacity is provided. According to the constitution, the intrusion of the static electricity can be prevented while the impedance matching in the transmission path to which the terminals 31c for high-speed signal are connected is successfully maintained. Here, the first diode 62A and the second diode 62B are examples of electrostatic protection device and, in addition to these, varistor etc. is mentioned as electrostatic protection device.

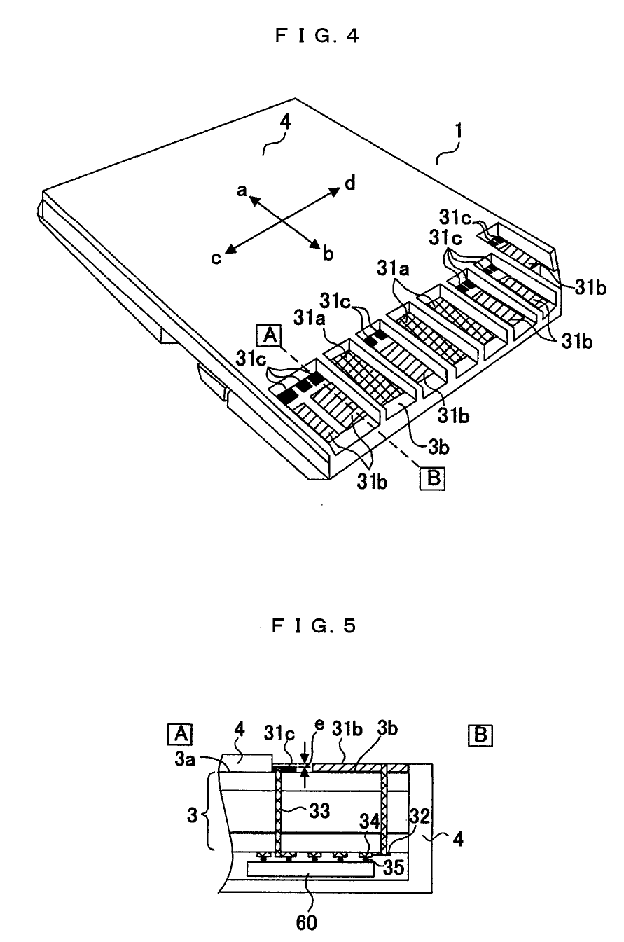

As illustrated in FIGS. 4 and 5, the terminals 31b for low-speed signal may be provided on the end side of the removable memory card 1 along a direction in which the terminals are arranged, and the terminals 31c for high-speed signal may be provided on the center side of the removable memory card 1. By doing so, it can be more difficult for a human body, such as his/her fingertips, to contact the terminals 31c for high-speed signal. As a result, the I/O circuit (I/O circuit for high-speed signals) in the LSI 60 can be more effectively protected from the static electricity. The direction in which the terminals are arranged in the removable memory card 1 includes both of a-b direction and c-d direction illustrated in FIG. 4.

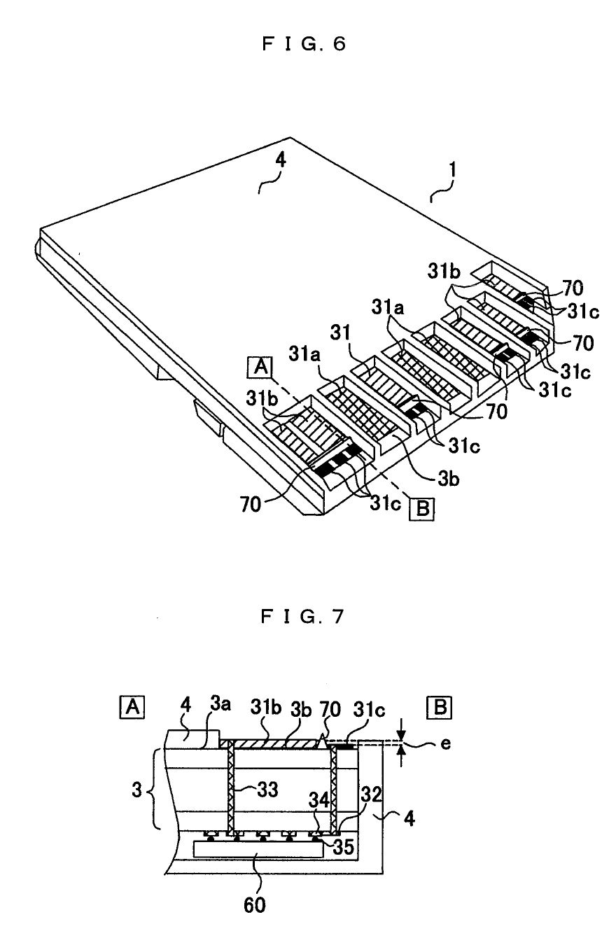

As illustrated in FIGS. 6 and 7, partitions 70 having a larger height dimension than the peripheral portions and protruding upward from the printed substrate 3 may be provided between the terminals 31b for low-speed signal and the terminals 31c for high-speed signal adjacent to each other to make it more difficult for the human body, such as his/her fingertips, to contact the terminals 31c for high-speed signal. As a result, the I/O circuit (I/O circuit for high-speed signal) in the LSI 60 can be more effectively protected from the static electricity. The partition 70 may be formed such that the sheet 4 made of hard PVC or the like and serving as the cover of the removable memory card, for example, is modified.

### Preferred Embodiment 2

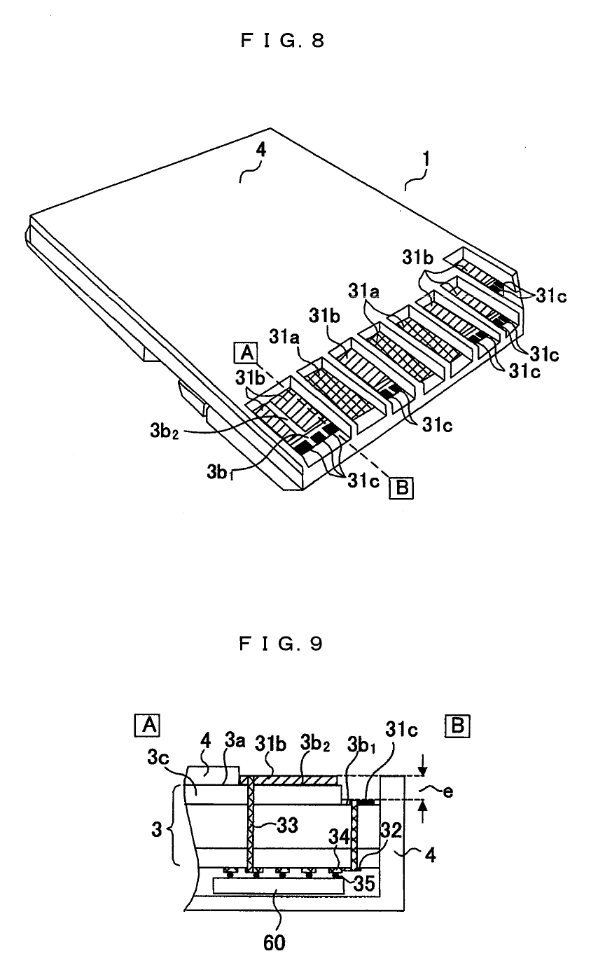

FIG. 8 is a perspective view of an example of a removable memory card according to a preferred embodiment 2 of the present invention. FIG. 9 is a sectional view of FIG. 8 cut along A-B line. The I/O circuit in the LSI 60, which is constituted in the same manner as in FIG. 3, is not shown in the drawings.

In the removable memory card according to the present preferred embodiment, terminals 31a, 31b and 31c used for connection to an outside host device (not shown) are provided on a surface of a printed substrate 3. On the printed substrate 3, an LSI 60, which controls the read and write of data with respect to a flash memory (not shown) provided in the removable memory card 1 in response to requests such as data READ/WRITE from the outside host device, is mounted by means of solder bumps 35 or the like.

The LSI 60 is connected to the terminals 31a, 31b and 31c by means of a via 33 in the printed substrate 3 and wiring lines 32. The printed substrate 3 comprising the terminals 31a, 31b and 31c, LSI 60, flash memory (not shown) and the like is covered with a sheet 4 made of hard PVC (polyvinyl chloride) or the like.

The present preferred embodiment is characterized in that, of the terminals 31a, 31b and 31c used for connection to the host device, the terminal 31b for low-speed signal and the power-supply/ground terminal 31a are provided on a surface-layer side of the printed substrate 3, while the terminal 31c for high-speed signal is provided on an inner-layer side of the printed substrate 3 as illustrated in FIG. 9. More specifically, a level difference e is provided between the surface height position of each of the terminals 31b and 31a and the surface height position of the terminal 31c. In order to provide the level difference e, the present preferred embodiment is constituted as follows. In a portion of the printed substrate 3 below the terminal 31b for low-speed signal and the power-supply/ground terminal 31a (second-terminal setting portion 3b₂), a surface layer 3c of the printed substrate 3 is provided at the same position as the surface layer 3c of the printed substrate 3 for any other portions are provided. On the other hand, in a portion of the printed substrate 3 below the terminal 31c for high-speed signal (first-terminal setting portion 3b₁), the surface layer 3c is selectively removed. Because the surface layer 3c of the printed substrate is thus selectively removed, the second-terminal setting portion 3b₂ is higher in position than the first-terminal setting portion 3b₁, which forms the level difference e.

Accordingly, when the fingertips of the human body, or the like, contact the terminals 31a, 31b and 31c, they first contact the power-supply/ground terminal 31a and the terminal 31b for low-speed signal. Therefore, the static electricity accumulated in the human body flows through the terminals 31a and 31b into a second diode 62B provided in a second bypass wire 63B, and then is discharged through the second diode 62B to the stable potential, or is discharged through the power-supply/ground terminal 31a to the stable potential. As a result, the I/O circuit 61 of the LSI 60 can be protected from the static electricity.

The transmission rate in the transmission of the signal through the terminals 31b for low-speed signal is low, and the impedance mismatch in the transmission path is not a major concern. On the other hand, the transmission rate in the transmission of the signal through the terminals 31c for high-speed signal is high, and the impedance mismatch in the transmission path can be a serious problem. In view of this, the following constitution is provided in the present preferred embodiment as is the case with the preferred embodiment 1. In the second bypass wire 63B to which the terminals 31b for low-speed signal are connected, a second diode 62B having a sufficiently high pressure resistance and a large load capacity is provided. On the other hand, in a first bypass wire63A to which the terminals 31c for high-speed signal are connected, a first diode 62A having a reduced load pressure resistance and a small load capacity is provided. According to the constitution, the I/O circuit (I/O circuit for high-speed signal) of the LSI 60 can be protected from the intrusion of the static electricity while the impedance matching in the transmission path to which the terminals 31c for high-speed signal is connected is maintained.

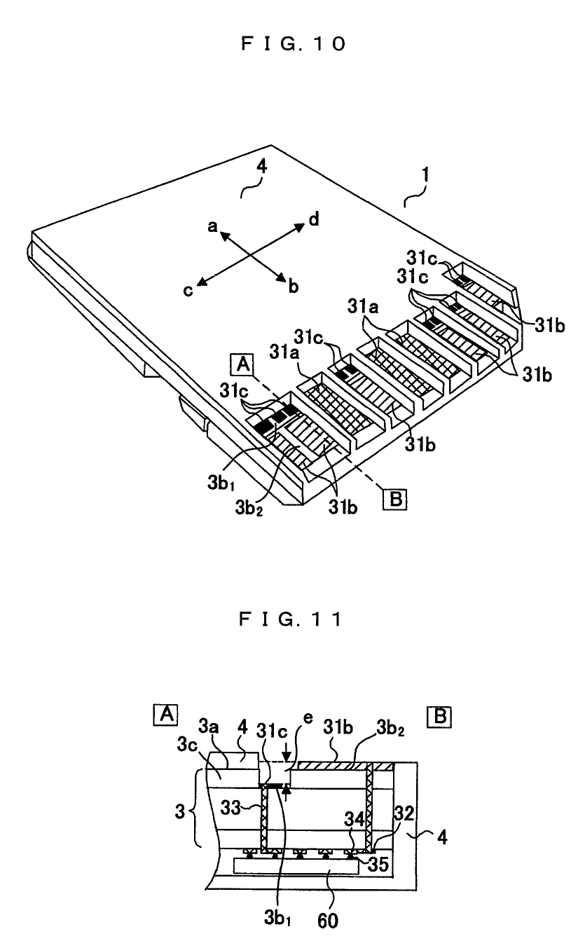

As illustrated in FIGS. 10 and 11, the terminals 31b for low-speed signal may be provided on the end side of the removable memory card 1 along a direction in which the terminals are arranged, and the terminals 31c for high-speed signal may be provided on the center side of the removable memory card. By doing so, it can be more difficult for a human body, such as his/her fingertips, to contact the terminals 31c for high-speed signal. As a result, the I/O circuit (I/O circuit for high-speed signal) in the LSI 60 can be more effectively protected from the static electricity. The direction in which the terminals are arranged in the removable memory card 1 includes both of a-b direction and c-d direction illustrated in FIG. 10.

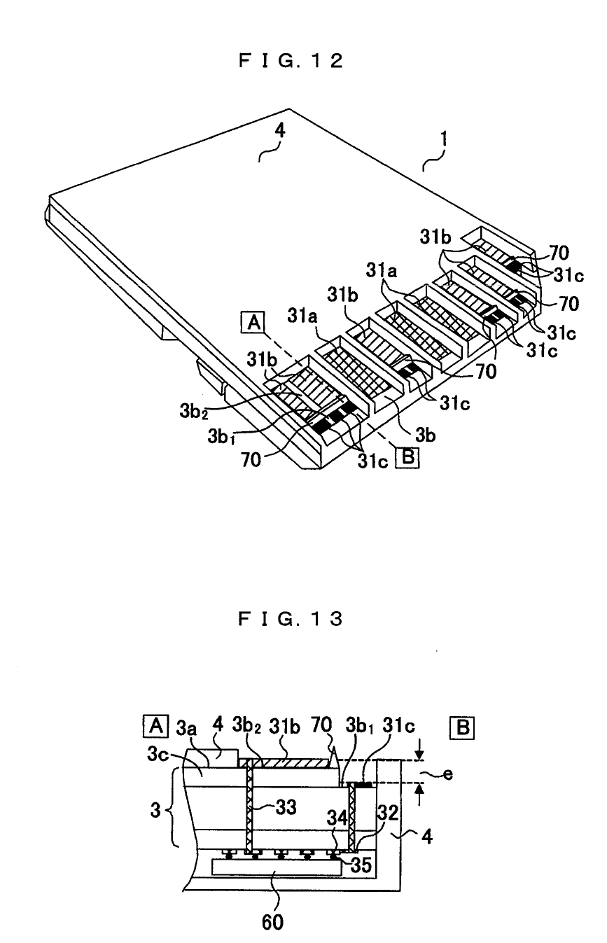

As illustrated in FIGS. 12 and 13, partitions 70 having a larger height dimension than the peripheral portions and protruding upward from the printed substrate 3 may be provided between the terminals 31b for low-speed signal and the terminals 31c for high-speed signal adjacent to each other to make it more difficult for a human body, such as his/her fingertips, to contact the terminals 31c for high-speed signal. The partitions 70 may be provided such that the sheet 4 made of hard PVC or the like and serving as the cover of the removable memory card, for example, is modified. As a result, the I/O circuit (I/O circuit for high-speed signal) in the LSI 60, to which the terminals 31c for high-speed signal are connected, can be more effectively protected from the static electricity.

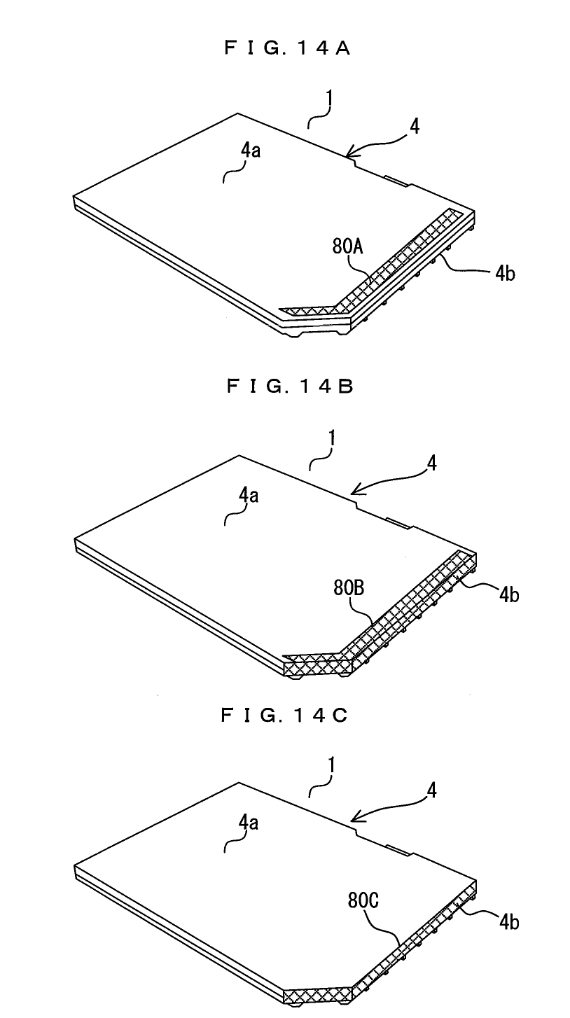

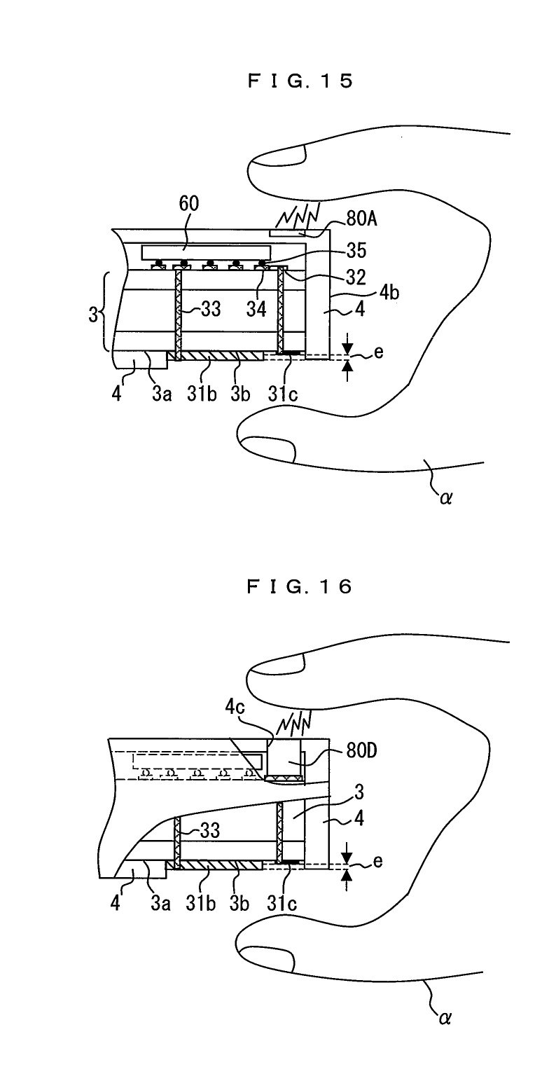

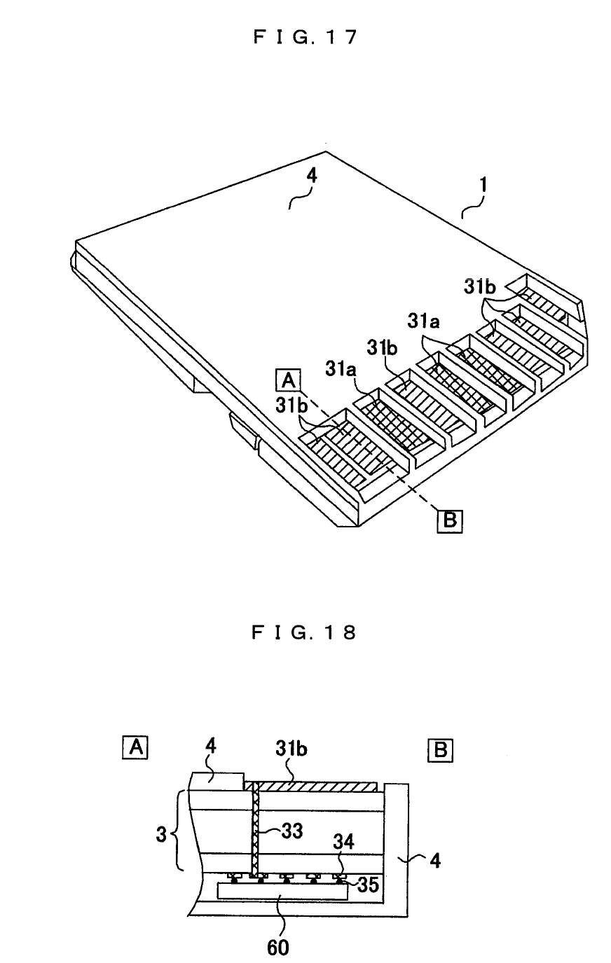

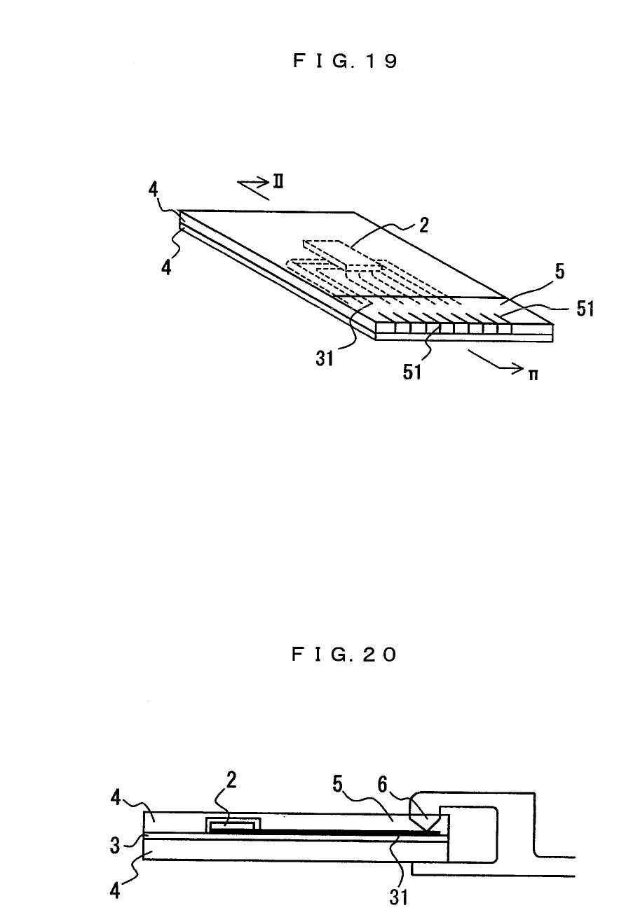

The constitutions according to the preferred embodiments described so far may further comprise a constitution illustrated in FIGS. 14A, 14B, 14C and 15. This modified embodiment is characterized in that ground pads 80A-80C are provided on a surface of the sheet 4. The ground pads 80A-80C are provided on a surface facing the terminal formulation surface 3a of the printed substrate 3, namely, a sheet surface 4a or a sheet end surface 4b. Moreover, the ground pads 80A-80C are provided along the sheet end surface 4b and in a shape extending over the entire length which covers positions facing the terminals 31a, 31b and 31c. Though not shown, the ground pads 80A-80C are connected to the ground potential of the printed substrate 3.

FIG. 14A illustrates the ground pad 80A where a pattern is formed on the sheet surface 4a alone. FIG. 14B illustrates the ground pad 80B having a pattern continuous from the sheet surface 4a through the sheet end surface 4b. FIG. 14C illustrates the ground pad 80C where a pattern is formed on the sheet end surface 4b alone. The ground pads 80A-80C are formed to be flush with the sheet surface 4a and the sheet end surface 4b. The ground pads 80A-80C are made of a conductive material. More specifically, conductive foil (metal foil or the like), a plating layer, a conductive resin layer, sheet 4 in which a metal pad is insert-molded, a dual-mold member (a member in which conductive resin and insulating resin are mixed and molded) or the like may constitute the ground pads 80A-80C.

In the case where the ground pads 80A-80C thus constituted are provided, as illustrated in FIG. 15, the possibility is increased that user's fingertips α, or the like, contact the ground pads 80A-80C before contacting the terminals 31a, 31b and 31c when the removable memory card 1 is used. Therefore, the static electricity accumulated in the user's body, which is an electrostatically-charged object, more easily flows through the ground pads 80A-80C to the ground potential of the printed substrate 3, which makes it more difficult for the static electricity to flow toward the terminals 31a, 31b and 31c. Accordingly, the electrostatic protection performance can be improved. In FIG. 15, the example of the contact made by the fingertips or the like is described referring to the structure illustrated in FIG. 14A, and, the same contact manner applies to the structures illustrated in FIGS. 14B and 14C.

As an alternative constitution, a ground pad 80D is provided on the printed substrate 3, and the ground pad 80D is exposed on the surface of the sheet 4 through a penetrating hole 4c formed in the sheet 4 as illustrated in FIG. 16.

While there has been described what is at present considered to be preferred embodiments of this invention, it will be understood that various modifications may be made therein, and it is intended to cover in the appended claims all such modifications as fall within the true spirit and scope of this invention.

What is claimed is:

1. A removable memory card comprising:
a printed substrate;
a first and second terminals for external connection provided on a terminal formation surface of the printed substrate; and
an LSI mounted on the printed substrate and connected to the first and second terminals, wherein
the setting height position of the first terminal is lower than the setting height position, of the second terminal on the terminal formation surface.

2. The removable memory card as claimed in claim 1, further comprising a first and second bypass wires provided on the printed substrate, the first and second bypass wiring dropping static electricity intruding into the first and second terminals to a stable potential through electrostatic protection devices, wherein
a second electrostatic protection device provided in the second bypass wire connected to the second terminal has a load capacity larger than a load capacity of a first electrostatic protection device provided in the first bypass wire connected to the first terminal.

3. The removable memory card as claimed in claim 1, wherein
the first and second terminals are terminals for inputting, outputting, or inputting and outputting a signal to an external device, and
a transmission rate of a signal transmitted through the first terminal is higher than a transmission rate of a signal transmitted through the second terminal.

4. The removable memory card as claimed in claim 1, wherein
the first terminal is a terminal to which a signal is inputted from outside, and the second terminal is a power-supply/ground terminal.

5. The removable memory card as claimed in claim 1, wherein
surfaces of the first and second terminals are metal-plated, and
a thickness of the metal plating of the first terminal is smaller than a thickness of the metal plating of the second terminal, and the setting height position of the first terminal is thereby lower than the setting height position of the second terminal.

6. The removable memory card as claimed in claim 1, wherein
the terminal formation surface of the printed substrate comprises a first terminal setting portion in which the first terminal is provided, and a second terminal setting portion in which the second terminal is provided, and
the height position of the first terminal setting portion is lower than the height position of the second terminal setting portion on the terminal formation surface, and the setting height position of the first terminal is thereby lower than the setting height position of the second terminal.

7. The removable memory card as claimed in claim 1, wherein
the second terminal is provided closer to a card-end side of the removable memory card along a direction in which the terminals are arranged in comparison to the first terminal.

8. The removable memory card as claimed in claim 1, wherein
a partition protruding upward from the printed substrate beyond the first and second terminals adjacent to each other is provided between these terminals.

9. The removable memory card as claimed in claim 1, further comprising a coating layer covering the printed substrate, wherein
a ground pad connected to a ground potential of the printed substrate is provided on at least one of a surface of the coating layer facing the terminal formation surface or the end surface which connects the other surface of the coating layer on the side of the terminal formation surface to the surface, and
the ground pad is provided in vicinity of the first and second terminals.

10. The removable memory card as claimed in claim 9, wherein
a surface of the ground pad is flush with the surface of the coating layer.

11. The removable memory card as claimed in claim 9, wherein
conducive foil constitutes the ground pad.

12. The removable memory card as claimed in claim 9, wherein
conductive resin constitutes the ground pad.

13. The removable memory card as claimed in claim 9, wherein
a plating layer constitutes the ground pad.

14. The removable memory card as claimed in claim 9, wherein
an insert-molded member constitutes the ground pad.

15. The removable memory card as claimed in claim 9, wherein
a dual-mold member constitutes the ground pad.

16. The removable memory card as claimed in claim 9, wherein
the ground pad is provided on the printed substrate, and
a penetrating hole through which the ground pad can be inserted is formed at a position of the coating layer at which the ground pad is provided, and
the ground pad is exposed on a surface of the coating layer through the penetrating hole.
